(19) United States
(12) Patent Application Publication
(10) Pub. No.: US 2011/0218111 A1
(43) Pub. Date: Sep. 8, 2011

(54) HIGH TEMPERATURE SUPERCONDUCTING PARALLEL CONDUCTORS, HIGH TEMPERATURE SUPERCONDUCTING COIL USING THE SAME, AND HIGH TEMPERATURE SUPERCONDUCTING MAGNET

(75) Inventors: Yota ICHIKI, Hitachinaka (JP); Tsuyoshi Wakuda, Hitachinaka (JP); Minseok Park, Hitachinaka (JP); Masaya Takahashi, Hitachinaka (JP)

(73) Assignee: Hitachi, Ltd.

(21) Appl. No.: 13/034,668

(22) Filed: Feb. 24, 2011

(30) Foreign Application Priority Data
Mar. 5, 2010 (JP) 2010-048686

(51) Int. Cl. H01F 6/06; H01B 12/10; H01L 39/02

(52) U.S. Cl. 505/163; 505/231; 174/125.1; 335/216

(57) ABSTRACT

A parallel conductor comprising a bundle of a plurality of high temperature superconducting wire materials, ends of the wire materials being electrically connected to each other, wherein each of the high temperature wire materials has at least one short-circuited portion where the wire materials are connected by means of a non-superconducting conductive material, and portions other than the short-circuited portion being covered with an insulating material.

### CLAIM OF PRIORITY

The present application claims priority from Japanese patent application serial No. 2010-048686, filed on Mar. 5, 2010, the content of which is hereby incorporated by reference into this application.

### FIELD OF THE INVENTION

The present invention relates to a high temperature superconducting magnet, a high temperature coil for the magnet and high temperature superconducting parallel conductors for them.

### BACKGROUND ART

Superconductor magnets for use in NMR (Nuclear Magnetic Resonance) apparatuses and MRI (Magnetic Resonance Imaging) apparatuses are designed to have a large accumulated magnetic energy (LI²/2, L is an inductance and I is an operating current). Therefore, a counter measure to quenching where a superconduction state of the superconductor shifts to non-superconducting state is required.

As a prior art technology for protecting the apparatuses from quenching, a protection resistor is connected in parallel with the superconducting coil thereby consuming the energy by means of the resistor, in general. This technology is effective in case of magnets of the type where current is always supplied to the coils from a power source, because current is shut to forcibly supply current to the protection resistor. However, in case of superconductor magnets for NMR apparatuses or MRI apparatuses that need high magnetic stability, current is supplied to a closed circuit composed of a superconducting coil and a permanent current switch. In this case, since the current is merely distributed at a ratio of resistance generated by quenching to the resistance of the protection resistor, a time constant of current attenuation depends on the generated resistance by quenching, the protection resistance and an inductance of the superconducting coil. Therefore, the apparatuses should be designed such that these parameters are within proper ranges so as to suppress a wire temperature of the wire to be one at which the wire is burned out at the time of quenching.

Regarding the quenching protection, there have been developed various methods. Patent document No. 1 discloses a method of controlling current that flows through the protection circuit wherein a diode instead of the resistor is connected in parallel with the superconducting coil when the magnet is excited and demagnetized by utilizing a switching voltage.

Patent document No. 2 discloses a method of protecting the circuit wherein a plurality of superconducting coils is connected in series. If a protection circuit comprising a diode and a heater is constituted, current based on a potential difference flows through the heater at the time of quenching, quenching of all superconducting coils is induced. These methods are useful for superconductor magnets that use low temperature superconductor wire materials.

### Prior Publications

Japanese patent laid-open S61-74308
Japanese patent laid-open 2007-234689

### SUMMARY OF THE INVENTION

A protection method for low temperature superconducting wire materials such as niobium has been established, but in case of magnets using high temperature superconducting wire materials, protection to quenching is much more difficult than that of low temperature superconductor wire materials. Since the high temperature superconductors have high critical temperatures, it is possible to make a temperature difference between the critical temperature and an operating temperature of the magnets. At the higher temperature the superconductor wire materials have a large specific heat, which has an advantage that the high temperature superconductor is hard to quench.

However, if once quench takes place by power failure or accidents of freezers, the advantage of the high temperature superconductor should become a disadvantage. That is, the fact that the quenching hardly takes place means that the quenching at a local position does not propagate to other positions. If a quenching area is small, energy in the coils is consumed within the local position. As a result, a temperature of the limited area increases rapidly to exceed a temperature at which the coils may be burned out.

As described above, in magnets driven by electric power it is possible to consume energy by flowing current through the protection resistor by breaking the power after detection of the quenching. In case where the magnets are operated in a permanent current mode it is impossible to forcibly change flow of current. Since the resistance that generates at the quenching by connecting the protection resistor and the superconducting coils in parallel is very much small compared with that of the inductance of the superconducting coils, a time constant of a current attenuation becomes long so that the coils cannot be protected.

It may be conceivable to quench the whole coils by turning on a heater disposed to the superconducting coils after detection of the quenching a method, the protection is difficult, when a time for necessary of detection, heating and temperature rise is considered. A method of recovering energy by inducing with a coil magnetically connected to the superconducting coils might be conceivable, a time is needed for current attenuation.

The present invention aims at preventing burn-out of the superconducting coils caused by a local temperature rise thereon when quenching takes place in a high temperature superconducting magnet under operation of the permanent current mode, and provides a high temperature superconducting coil useful for the above object and a high temperature superconducting parallel conductor.

The present invention provides a high temperature superconducting parallel conductor constituted by a plurality of high temperature superconducting wires, wherein the plural high temperature superconducting wires are arranged such that each terminal end of the wires is electrically connected with the terminal ends of adjoining wires, and wherein the high temperature wires each has at least one short-circuited position other than the terminal end, which is connected with adjoining wires by means of a non-superconducting conductive material, portions other than the short-circuited portion being covered with an insulating material. The parallel conductors or wires include ones, which are wound on a spool or ones, which are wires before being wound on the spool.

Each of the wires has different winding numbers and they are connected by means of the non-superconducting conductive material to form the short-circuited portions.

The short-circuited portions may be formed periodically along approximately the whole length of the conductors or wires. Although the short-circuited portions may preferably be formed throughout the whole length of the wires, the short-circuited portions are formed at needed positions if desired. There are such cases that the whole length is not always literally the whole length. Further, the short-circuited portions may preferably periodically be formed on the parallel wires, there may be cases where the short-circuited portions are not periodically. Some difference in distance between the short-circuited portions may be allowed. Accordingly, the “periodically” should not always be interpreted literally. When the short-circuited portions are formed at plural positions, the short-circuited portions should not be electrically contacted.

The insulating material is resins or glass fibers, and the glass fibers may be, if necessary, impregnated with resin varnish and impregnated glass fiber is cured.

The high temperature superconducting wire materials can be magnesium diboride (MgB₂) or different oxides containing bismuth and/or yttrium oxides. Since the materials are well known and described in various patents and publications, detailed descriptions will be omitted for the sake of simplification in the present specification.

The non-superconducting conductive material for forming the short-circuited portions can be solder pastes or metal powder pastes. The resistance of the non-superconducting materials should preferably be as small as possible.

The number of the superconductor wires is preferably 2 or three. Each 2 of the wires are short-circuited even when the number is more than 2. The parallel wires are wound in a coil form to constitute a high temperature superconducting coil. In this high temperature superconducting coil it is preferable that the high temperature superconducting wires have short-circuited portions of different winding numbers (short-circuited portions between turns) where the wires are connected by means of the non-superconducting conductive material.

The present invention can provide a high temperature superconducting magnet having a permanent current switch connected to the high temperature superconducting coil.

The present invention further provides a high temperature superconducting magnet of a conductive cooling type wherein the coil is cooled by a freezer without a coolant, which is known in the art.

In addition, the present invention provides a high temperature superconducting coil, which comprises the superconducting coil wound in a coil form, and a permanent current switch, wherein the superconducting is constituted by high temperature superconducting wire materials wound in parallel with each other, each of the wires having short-circuited portions electrically connected to other superconductor wires by means of a non-superconducting conductive material. This structure can make small inductance formed by the short-circuited portions and the loops formed by the coils.

The superconducting coil of the present invention is constituted such that the plural high temperature superconducting wire materials secure electrical insulation and thermal insulation by the resin or the glass fiber whereby heat generated at portions where quenching takes place prevents from dispersing to other portions.

The present invention provides a superconducting coil that suppresses the propagation of quenching by short-circuited two wires of three wires.

In addition, the present invention provides a high temperature superconducting coil structure wherein different turns are short-circuited to let current flow thereby to by-pass the quenched portions for the case where quenching takes place in all of the high temperature superconducting wire materials. Another aspect of the present invention provides a parallel conductor comprising a bundle of a plurality of high temperature superconducting wire materials, ends of the wire materials being electrically connected to each other, wherein each of the high temperature wire materials has at least one short-circuited portion where the wire materials are connected to each other by means of a non-superconducting conductive material, and portions other than the short-circuited portion being covered with an insulating material.

According to the present invention, it is possible to avoid a local temperature rise at the quenched portions because current flows the short-circuited portion and by-passes the quenched portions.

### BRIEF DESCRIPTION OF THE DRAWINGS

FIG. 1A shows a diagrammatic view of a high temperature superconducting coil of embodiment 1.

FIG. 1B shows a cross sectional view of the super conductor parallel coil of FIG. 1A.

FIG. 2A shows a flow current in a normal state (superconducting state) before quenching takes place in a circuit of the high temperature superconducting magnet of embodiment 1.

FIG. 2B shows a flow current in a state where quenching takes place in the circuit of the high temperature superconducting magnet of embodiment 1.

FIG. 2C shows an equivalent circuit showing a change of current flow at the time of quenching in a circuit of the high temperature superconducting magnet of embodiment 1.

FIG. 3A shows a diagrammatic view of a high temperature superconducting coil of embodiment 2.

FIG. 3B shows a short-circuited portion in parallel conductors of the high temperature superconducting coil of embodiment 2.

FIG. 4A shows a diagrammatic view of a high temperature superconducting coil of embodiment 3.

FIG. 4B shows a cross sectional view showing a short-circuited portion at a position between a short-circuited portion of the plural conductors of the high temperature superconducting coil and the adjoining turns.

FIG. 5 shows a diagrammatic view of a high temperature superconducting magnet of the present invention.

FIG. 6 shows a cross sectional view of a conductive cooling type superconductor magnet.

### DESCRIPTION OF THE PREFERRED EMBODIMENTS

In the following the present invention will be explained by reference to drawings.

### Embodiment 1

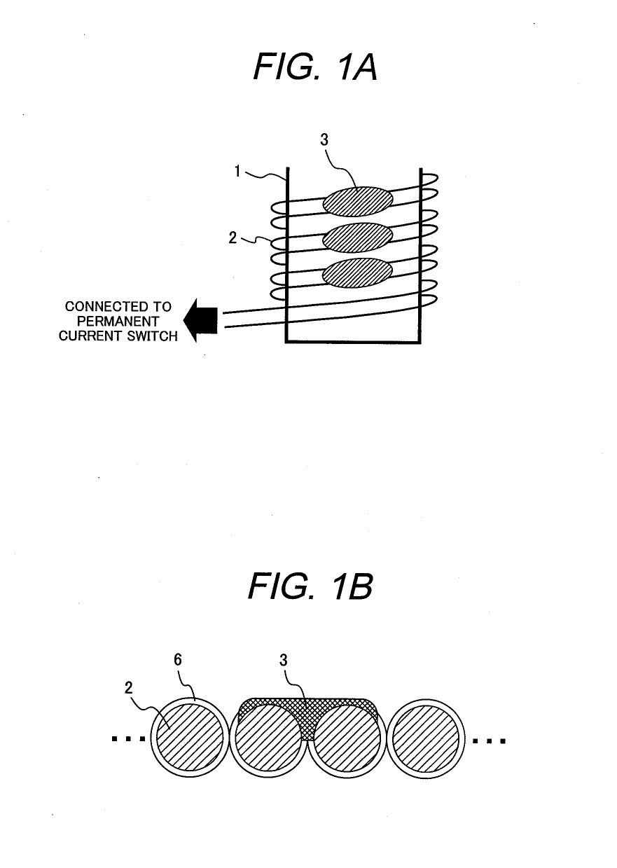

FIG. 1A is a diagrammatic view for explaining a superconducting coil of embodiment 1. Two high temperature superconducting wire materials 2 are mutually wound on a spool 1. In the drawing though there are depicted gaps among the wires for the sake of easy observation, the wires should preferably be wound densely without the gaps as shown in FIG. 1B so as to decrease resistance of the short-circuited portions 3 and increase magnetic homogeneity.

Each of the high temperature superconducting wire materials is covered with an insulating cover 6 made of resin or glass fiber as shown in FIG. 1B to thereby secure electrical insulation and to secure thermal insulation for preventing propagation of quenching among the wires.

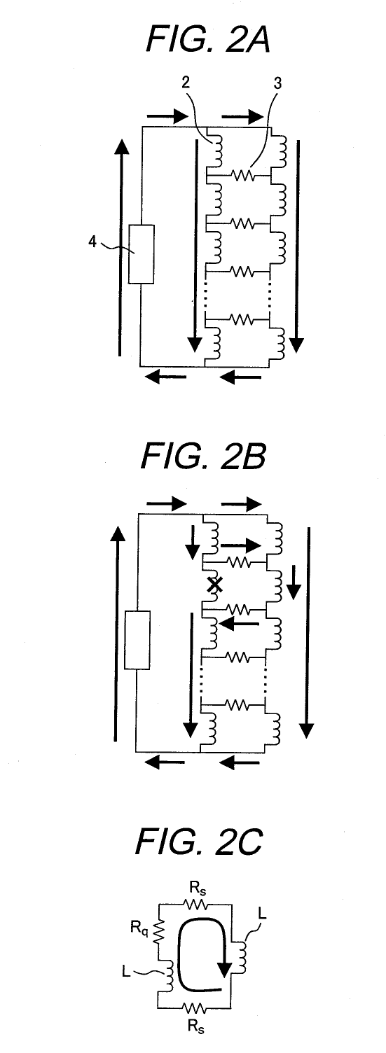

The equivalence circuits of the superconductor magnet of this embodiment are shown in FIGS. 2A to 2C. Arrows in figures indicate flows of current. FIG. 2A shows a flow of current in the normal state (superconducting state) before quenching wherein a closed circuit is constituted by a permanent current switch 4 and two superconductor wire materials connected to the switch 4 in parallel where permanent current flows. Current does not flow through the short-circuited portions 3 of the wire materials. FIG. 2B shows a flow of current when quenching occurs at a position marked by X.

When quenching occurs, current flow changes so as to by-pass the quenched portion. An equivalent circuit of the current flow change at the quenching is shown in FIG. 2C. A time constant of the current change is calculated in accordance with L/(Rq+2Rs) where a resistance Rq is a resistance generated at the quenched portion and an inductance L is an inductance of the loop. If this time constant is shorter than a time t, which is needed until the wire material is burned out, the circuit is protected. Accordingly, it is preferable to design the resistance Rs of the short-circuited portion so as to meet the relation t>L/(Rq+2Rs).

An inductance L in the loop constituted by the short-circuited portion shown in FIG. 2C and the coil portion is determined almost by its inner inductance μl/8π (l: a length of wires) when the wires are wound closely adjoined. Since a magnetic transmittance in vacuum is 4π×10⁻⁷ an inductance per a unit length is estimated as 0.5×10⁻⁷ [H/m]. In order to by-pass current at the time of quenching, the resistance Rs of the short-circuited portion should be sufficiently smaller than that of the resistance Rs generated at the time of quenching. Accordingly, the time constant is determined almost by L/Rs. Therefore, the resistance Rs generated at the time of quenching and a desired time constant are taken into consideration to decide the inductance L, i.e. a distance between the short-circuited portions.

If the high temperature superconductor is magnesium diboride (MgB₂) whose critical temperature is 39 K, we obtained experiment results that the wires are burned out in one second after occurrence of quenching if current is supplied at a load rate of 90%. Since the order of the resistance Rs generated at the time of quenching is 10⁻⁵ to 10⁻⁴Ω, the inductance should be 10⁻⁶ H or less if the time constant is set to be 0.1 second. From the above, the distance between the short-circuited portions will be allowed until 10 m.

In view of productivity, it is preferable that the distance between the short-circuited portions should be as large as possible within an acceptable range because the number of the short-circuited portions should be as small as possible. Accordingly, the distance between the short-circuited portions should preferably be in a range of 1 to 20 m, more preferably be in a range of 5 to 15 m from the center in a lengthwise direction of the short-circuited portions (along the length of the parallel conductors). Further, a length of each short-circuited portion (in a direction of the lengthwise of the parallel conductors) should have a resistance Rs smaller than the resistance Rq at the time of quenching. Although there is no limitation, 5 to 30 mm, more particularly 8 to 15 mm is preferable. For example, if a resistance of solder is 3×10⁻⁸[Ω], and a distance between the conductors and a thickness of the solder are 1 mm, respectively, it is possible to the Rs to be 10⁻⁶[Ω] or less if the length of the solder is 30 mm or less.

### Embodiment 2

In embodiment 1 the two high temperature superconducting wire materials were wound mutually. In case of two wires operation of the magnet must be done at a load rate of 50% or less in order to bear the operation current by one of the wires when one wire quenches. This means that the operation utilizing the full performance of the wires cannot be done. An increase in the number of the wires makes it possible to increase a quantity of current to be born by wires if one wire quenches so that a load rate of the normal operation can be increased. When the number of wires is three, the load rate per one wire can be 67% per the full performance, and if the number is four, the load rate can be 75%. However, since an increase in the number of wires makes it difficult to wind the wires, the number should be decided by taking into consideration that.

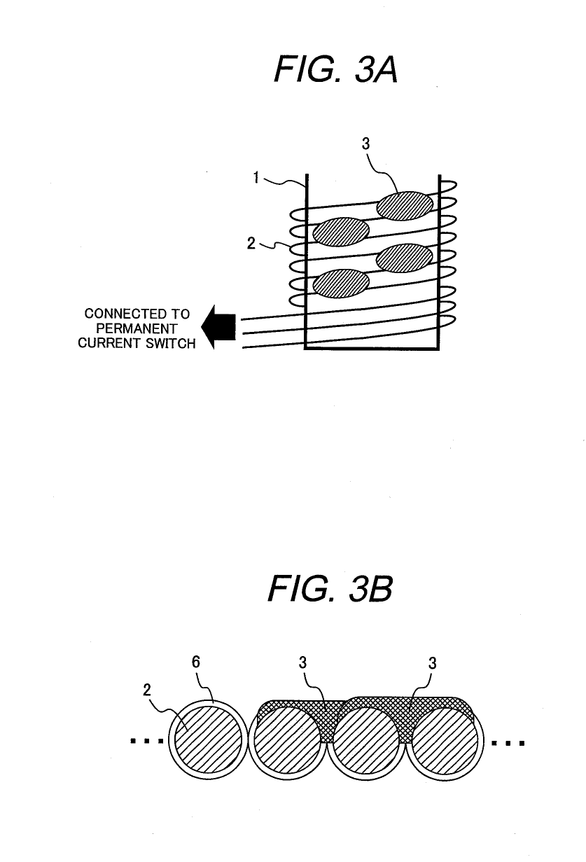

FIG. 3A shows a diagrammatic view of a superconducting coil wherein three wires 2 are used. As shown in FIG. 3A, the three wires are not short-circuited altogether, but two of them should preferably be short-circuited. If the three wires are short-circuited altogether, heat at the short-circuited portion concentrates upon it when the quench current by-passes so that there is an increased risk of quenching all of the wires.

FIG. 3B shows a cross sectional view of the short-circuited portion 3 in FIG. 3A. As same as FIG. 1B, the short-circuited portion is formed by removing the insulating coating 6.

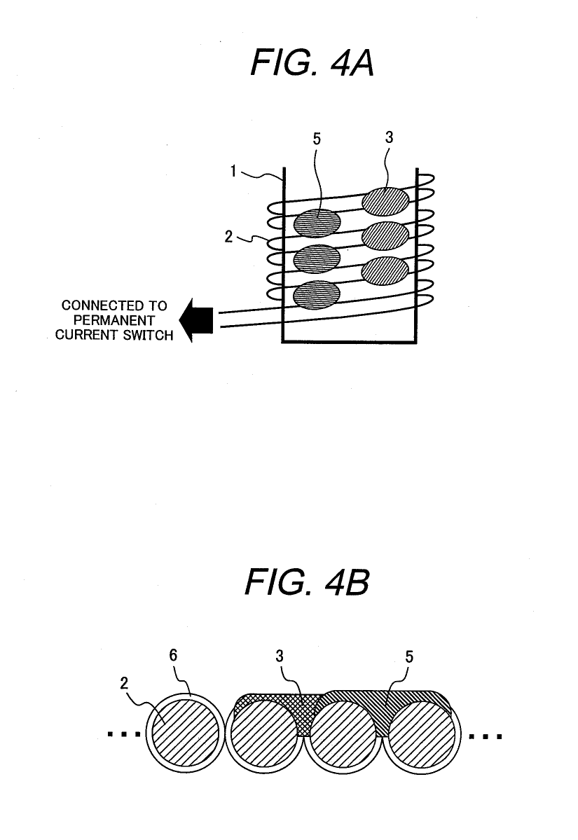

As a method of by-passing current when all of the plural superconducting wires quench, a method shown in FIG. 4A is proposed wherein since magnetic field reduces in one turn to lengthen the time constant, and since current flows during magnetization, a counter measure such as a slow speed of magnetization may be necessary. In FIG. 4A, the short-circuited portions 3 are short-circuited portions between the parallel conductors and the short-circuited portions 5 are short-circuited portion between turns of the wires. FIG. 4B shows a cross sectional view thereof.

According the above mentioned embodiment, it is possible to by-pass current at the quenched portion. Although it may be possible to re-start the operation of the magnet as it is, it is possible to adopt a conventional protection method wherein the coils are heated by a heater is jointly used.

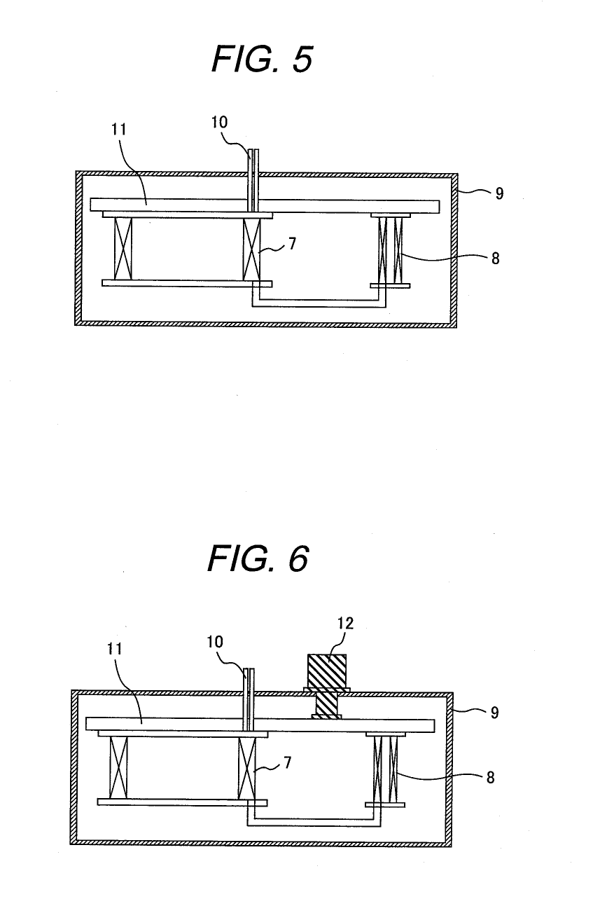

FIG. 5 shows a cross sectional view of a high temperature superconducting magnet to which the high temperature superconducting coil of the present invention is applied wherein the high temperature superconducting coil 7 is supported on a supporting plate 11, a permanent current switch 8 and a current lead 10 are connected to the coil, and these elements are accommodated in a cooling vessel 9. The structure and operation are well known; detailed explanations will be omitted for simplification.

FIG. 6 shows a cross sectional view of a conductive type cooling superconductor magnet, which does not use a cooling medium. A freezer 12 cools the superconducting coil by means of a supporting plate 1. The structure and operation are also well known; detailed explanations will be omitted for simplification.

### REFERENCE NUMERALS

1; spool, 2; high temperature superconducting wire material, 3; short-circuited portion with non-superconducting conductive material, 4; permanent current switch, 5; short-circuited portions of different turns with the non-superconductive conductive material, 6; insulating material, 7; high temperature superconductor switch, 8; permanent current switch, 10; current lead, 12; freezer

What is claimed is:

1. A high temperature superconducting parallel conductor comprising a bundle of a plurality of high temperature superconducting wire materials, ends of the wire materials being electrically connected to each other, wherein each of the high temperature wire materials has at least one short-circuited portion where the wire materials are connected to each other by means of a non-superconducting conductive material, and portions other than the short-circuited portion being covered with an insulating material.

2. The high temperature superconducting parallel conductor according to claim 1, wherein a plurality of the short-circuited portions are periodically formed over substantially the entire length of the wire material.

3. The high temperature superconducting parallel conductor according to claim 1, wherein the insulating material is resin or glass fiber.

4. The high temperature superconducting parallel conductor according to claim 1, wherein the plural high temperature superconducting wire materials are magnesium diboride or a oxide containing bismuth and/or yttrium.

5. The high temperature superconducting parallel conductor according to claim 1, wherein the non-superconducting conductive material is a solder or metal paste.

6. The high temperature superconducting parallel conductor according to claim 1, wherein the number of the plural high temperature superconducting wire materials is 3 or more, in which each two of them are short-circuited.

7. A high temperature superconducting coil comprising the parallel conductor according to claim 1, wherein the conductor is wound in a coil form.

8. The high temperature superconducting coil according to claim 7, wherein the high temperature superconducting wire materials each having different winding number are connected by means of the non-superconducting conductive material to form the short-circuited portions.

9. A high temperature superconducting magnet comprising the high temperature superconducting coil according to claim 7, and a permanent current switch connected to the high temperature superconducting coil.

10. The high temperature superconducting magnet according to claim 9, wherein the high temperature superconducting magnet is cooled by a freezer without cooling medium.
